(19) United States
(12) Patent Application Publication
(10) Pub. No.: US 2023/0141990 A1
(43) Pub. Date: May 11, 2023

(54) Quantum Dot Light-emitting Device and Display Device

(71) Applicant: Najing Technology Corporation Limited, Hangzhou, Zhejiang (CN)

(72) Inventors: Hailin WANG, Hangzhou, Zhejiang (CN); Qile HU, Hangzhou, Zhejiang (CN)

(21) Appl. No.: 17/912,863

(22) PCT Filed: Mar. 22, 2021
(86) PCT No.: PCT/CN2021/082061

§ 371 Date: Sep. 20, 2022

(30) Foreign Application Priority Data
Mar. 24, 2020 (CN) 202010212344.4

(51) Int. Cl. H01L 33/50; H01L 33/60

(52) U.S. Cl. CPC H01L 33/507; H01L 33/60; H01L 2933/0083

(57) ABSTRACT

The present disclosure discloses a quantum dot light-emitting device and a display device. The quantum dot light-emitting device includes: a concave frame having a chip mounting region, a light-emitting diode chip disposed in the chip mounting region, the light-emitting diode chip adapted to emit a first light; a quantum dot layer disposed on the light exit direction of the light-emitting diode chip; a functional layer disposed between the light-emitting diode chip and the quantum dot layer, the functional layer is a first functional layer or a second functional layer; the first functional layer has a reflectivity greater than or equal to R with respect to the first light having angle of incidence less than or equal to i, and the first functional layer has a reflectivity less than R with respect to the first light having angle of incidence greater than i, wherein R≤90%, i>0°.

### CROSS-REFERENCE TO RELATED APPLICATION

The disclosure is a national stage application of International Patent Application No. PCT/CN2021/082061, which is filed on Mar. 22, 2021, and claims a priority to Chinese patent application No. 202010212344.4, filed to the China National Intellectual Property Administration (CNIPA) on Mar. 24, 2021 and entitled “Quantum Dot Light-emitting Device and Display Device”.

### TECHNICAL FIELD

The present disclosure relates to a quantum dot light-emitting device, particularly to a quantum dot, light-emitting device and a display device.

### BACKGROUND

Quantum dots are special nanocrystalline materials that can emit light at a specific wavelength when excited by blue or ultraviolet light. At present, quantum dots have three main application forms in the liquid crystal display, as shown in FIG. 1A, 1B, 1C: the first form is on-surface form as shown in FIG. 1A, i.e. a quantum dot layer 3a is disposed on a light guide layer 1a, light from the light source 2a passes through the light guide layer 1a and reaches to the quantum dot layer 3a, thereby exciting the quantum dots in the quantum dot layer 3a, a reflecting layer 4a is disposed on one side of the light guide layer 1a away from the quantum dot layer 3a for increasing the utilization of energy. The second form is on-edge form as shown in FIG. 1B, i.e. a quantum dot layer 3b is disposed on the incident light side of the light guide layer 1b, after light from the light source 2b passing through quantum dot layer 3b, the excited light generated by the quantum dots enters the light guide layer 1b, a light reflecting layer 4b is disposed away from the light exit side of the light guide layer 1b. The third form is on-chip as shown in FIG. 1C, a quantum dot layer 3c is directly disposed on a light source 2e, thus form integrally a package body. The first and second forms have existing commercial products for sale, but for the third form, due to the quantum dots are disposed closest to heat source and radiation, requirements of the quantum dots stability and packaging technique are high, currently there is no commercial product. However, in the on-chip form, quantum dots can be excited at the light source, the material consumption of quantum dots is very low (about one ten-thousandth of the on-surface form, one percent of the on-edge form), in addition, on-chip form is compatible with existing components used by downstream manufacturers, so introduction or switch cost is almost zero, so it is an ideal application form of quantum dot backlight.

Patent application number CN201310699961.1 discloses a white LED device based on the quantum dots including a LED chip, a light conversion layer coated on the LIED chip and a carrier carrying the LED chip, the light conversion layer is provided with luminescent material, the luminescent material comprises quantum dots and a transparent polymer material.

Patent application number CN201680085267.2 discloses a quantum dot light-emitting device, including: a light-emitting diode chip disposed on a frame; a first resin encapsulating the LED chip on the frame; a heat sink provided on the first resin; a second resin, covering the heat sink and including quantum dots dispersed therein.

Patent application number CN201710154475.X discloses a quantum dot LED packaging structure, including a bracket, a LED chip fixed to the bracket, a metal wire connecting the LED chip and the bracket, and a quantum dot package and a water-oxygen barrier structure encapsulating the LED chip on the bracket, the water-oxygen bather structure encapsulates the quantum dot package, so as to isolate quantum dots from the environment.

Patent application number CN201710642890.X discloses a quantum dot LED packaging structure, including: a non-metallic bracket including a bottom plate and a surrounding sidewall to which the bottom plate is connected; a LED chip fixed on the bottom plate, thickness of the LED chip being less than the height of the sidewall; a first barrier layer encapsulating the sidewall, the LED chip and surface of the bottom plate; surface of the first barrier layer corresponding to the LEI) chip has a recess slot; a quantum dot silicone layer is disposed in the recess slot; a second barrier layer encapsulating the first barrier layer and the quantum dot silicone layer; and an undoped silicone layer coated on the surface of the second barrier layer.

The above patents all relate to on-chip package, at present, most studies of on-chip package focus on how to improve the light efficiency and improve the barrier properties of the package body.

### SUMMARY

An object of the present disclosure is to provide a quantum dot light-emitting device, to solve poor stability of the quantum dots in the on-chip package at high light intensity and high temperature.

Another object of the present disclosure is to provide a display device of good stability.

To achieve the above objects, the present disclosure provides a quantum dot light-emitting device, including a concave frame having a chip mounting region, further including:

a light-emitting diode chip disposed in the chip mounting region, the light-emitting diode chip adapted to emit a first light;

a quantum dot layer disposed on the light exit direction of the light-emitting diode chip;

a functional layer disposed between the light-emitting diode chip and the quantum dot layer, the functional layer is a first functional layer or a second functional layer; the first functional layer has a reflectivity greater than or equal to R with respect to the first light having angle of incidence less than or equal to i, and the first functional layer has a reflectivity less than R with respect to the first light having angle of incidence greater than i, wherein R≤90%, i>0°; the second functional layer is a reflective polarizing film layer, the second functional layer reflects light having a first polarized state in the first light and transmits light having a second polarized state in the first light, the light having the first polarized state is orthogonal to the light having the second polarized state.

Further, the first functional layer has an absorption rate less than 0% with respect to visible light, preferably, the first functional layer has an absorption rate less than 1% with respect to visible light.

Further, R≥30%, preferably, R≥60%.

Further, 0°<i≤45°, preferably, 15°<i≤30°.

Further, the quantum dot light-emitting device further including a first barrier layer and a second barrier layer disposed on a first surface and a second surface of the quantum dot layer respectively.

Further, the functional layer is disposed opposite to the region having, the maximum light intensity of the light-emitting diode chip.

Further, the second functional layer has a reflectivity greater than or equal to 80% with respect to the light having the first polarized state, the second functional layer has a transmissivity greater than or equal to 80% with respect to the light having the second polarized state.

Further, the wavelength of the first light is 400 nm-480 nm, preferably, the wavelength of the first light is 430 nm-470 nm.

Further, the first functional layer includes at least one photonic crystal layer, the photonic crystal layer includes one or more of one-dimensional photonic crystal, two-dimensional photonic crystal and three-dimensional photonic crystal.

Further, the first functional layer includes 1 to 6 layers of the photonic crystal layer, a thickness of each of the photonic crystal layer is the same or different, the thickness of each photonic crystal layer is 200 nm-340 nm, preferably, the first functional layer includes 1 to 4 layers of the photonic crystal layer.

Further, the quantum dot light-emitting device does not include the concave frame.

According to another aspect of the present disclosure, there is also provided a display device, including the quantum dot light-emitting device of the present disclosure.

Compared with the prior art, the quantum dot light-emitting device of the present disclosure can reduce the light intensity coming from the LED (light-emitting diode) chip toward the central region of the quantum dot layer, so that light reaching to every region of the quantum dot layer is relatively uniform, thus contributing to improve the light resistance capability of the quantum dot layer. Moreover, since each region of the quantum dot layer is subjected to a more uniform light intensity compared with the prior art, lifetime of the quantum dot layer can be improved. Additionally, the functional layer may also isolate heat produced from the LED chip to some extent, increasing the stability of the upper part of the quantum dot layer.

### BRIEF DESCRIPTION OF THE DRAWINGS

FIG. 1A, 1B, 1C respectively depict three application forms of quantum dots material in a liquid crystal display in the prior art.

FIG. 2A schematically depicts one embodiment of quantum dot light-emitting device.

FIG. 2B schematically depicts one embodiment of quantum dot light-emitting, device.

FIG. 2C schematically depicts one embodiment of quantum dot light-emitting device.

FIG. 3 depicts a light distribution curve of the light-emitting diode chip in an embodiment.

FIG. 4 depicts a curve of relation between transmittance T of light with frequency in the band gap center of the photonic crystal and the cycle layer number N of the photonic crystal. In the figures, 100 represents concave frame; 101 represents package cavity; 200 represents light-emitting, diode chip or LED chip; 300 represents functional layer; 3001 represents first functional layer; 3002 represents second functional layer; 400 represents quantum dot layer.

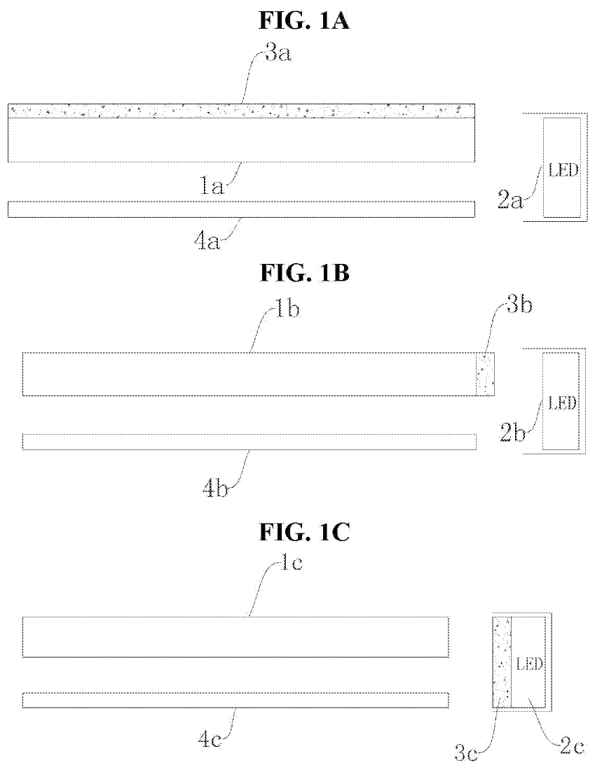

### DETAILED DESCRIPTION

Next, in connection with the detailed embodiments, the present disclosure is further described, and it is necessary to explain that new embodiments may be formed in any combination of the various embodiments or any of the technical features described below.

It, may be understood that the term “a” or “an” should be understood to mean “at least one” or “one or more”, that is, in one embodiment, the number of an element may be one, and in other embodiments, the number of the element may be multiple. The term “a” or “an” cannot be understood as a limitation on the number.

It should be understood by those skilled in the art that in the disclosure of the present application, the orientation or positional relationship indicated by the terms “center”, “longitudinal”, “transverse”, “upper”, “lower”, “front”, “back”, “left”, “right”, “vertical”, “horizontal”, “top”, “bottom”, “inside”, “outside”, “clockwise”, “counterclockwise”, etc. is based on the orientation or positional relationship shown in the drawings, which is merely for the convenience of describing the present disclosure and simplifying the description, and does not indicate or imply that the mentioned apparatus or element must have a particular orientation and be constructed and operated in the particular orientation. Therefore, the above terms cannot be understood as a limitation of the present disclosure.

Terms such as “first”, “second” in the disclosure are used to distinguish between similar objects, and are not necessarily used to describe a specific sequence or order.

The terms “include” and “have” and any variations thereof are intended to cover a non-exclusive inclusion, so that a process, a method, a system, a product, or a device that includes a series of units, is not necessarily limited to expressly listed units, but may include other units that are not expressly listed or that are inherent to such process, method, product, or device.

In the present disclosure, when an element such as a layer, a film, a region, or a substrate is “in”, “on” the other element, it can be directly on the other element or there is an intermediate element between them.

In the present disclosure. “a quantum dot layer” or “a functional layer” does not represent it only has one-layered structure, its internal structure may be a multilayer.

The terms “about” or “approximately” in the present disclosure means within one or more standard deviation of the value stated, such as within +10%, or ±5%.

Term “angle of incidence” or “incident angle” in the specification and claims in the present disclosure refers to the angle between the incident light and normal line to the light incident surface.

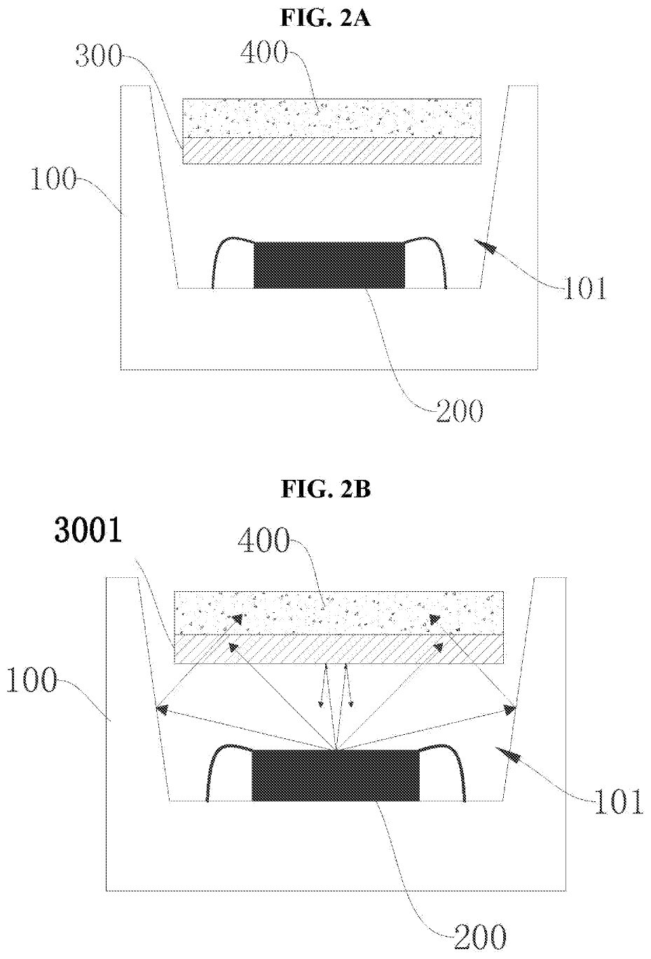

The present disclosure provides a quantum dot light-emitting device, an example as shown in FIG. 2A, including a concave frame 100, a light-emitting diode chip 200, a functional layer 300 and a quantum dot layer 400. The concave frame 100 has a chip mounting region, the light-emitting diode chip 200 is disposed in the chip mounting region of the concave frame 100. The light-emitting diode chip 200 is adapted to emit a first light, the quantum dot layer 400 is disposed on the light exit direction of the light-emitting diode chip 200, the functional layer 300 is disposed between the light-emitting diode chip 200 and the quantum dot layer 400, the functional layer 300 is a first functional layer 3001 or a second functional layer 3002.

The first functional layer 3001 has a reflectivity greater than or equal to R with respect to the first light having angle of incidence less than or equal to i, and the first functional layer 3001 has a reflectivity less than R with respect to the first light having angle of incidence greater than i, wherein R≤90%, i>0°.

The second functional layer 3002 is a reflective polarizing film layer, the second functional layer 3002 reflects light having a first polarized state in the first light and transmits light having a second polarized state in the first light, the light having the first polarized state is orthogonal to the light having the second polarized state.

One effect of the functional layer 300 is to make the intensity of the first light reaching to the respective region of the quantum dot layer 400 relatively uniform, thereby improving the light resistance of the quantum dot layer 400. The functional layer 300 may be a multilayered structure, it may be a combination of the first functional layer 3001 and the second functional layers 3002.

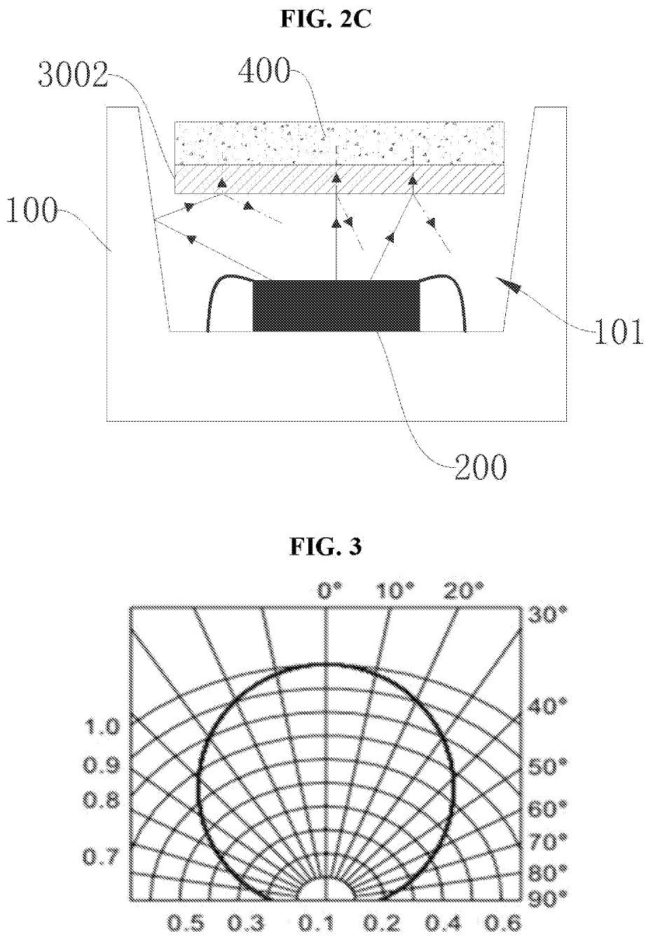

Typically, the light pattern emitted from the LED chip is near-Lambertian light source. FIG. 3 shows a light distribution curve of the LED chip tested by the inventors. When the quantum dot layer is disposed directly above the LED chip, the light intensity of the center of the quantum dot layer is stronger than the peripheral region of the quantum dot layer. The light-resistant capability of each region of the quantum dot layer is consistent, therefore, in the conventional package structure, when the central region of the quantum dot layer reaches a tolerable illumination limit, the peripheral region of the quantum dot layer does not reach the tolerable illumination limit, which means the peripheral region of the quantum dot layer is exposed to more light, thus it tends to age and has a reduced lifetime.

In some embodiments, the package cavity 101 has a reflective inner wall. When a first functional layer 3001 is disposed between the quantum dot layer 400 and the LED chip 200, as shown in FIG. 2B, reflectivity of the first functional layer 3001 to the first light having smaller incident angle is big, reflectivity of the first functional layer 3001 to the first light having bigger incident angle is small, and the incident angle of the first light emitted from the LED chip 200 toward the central region of the quantum dot layer 400 onto the first functional layer 3001 is smaller, and the incident angle of the first light emitted from the LED chip 200 toward the peripheral region of the quantum dot layer 400 onto the first functional layer 3001 is bigger, therefore, the first light toward the central region of the quantum dot layer 400 is more reflected by the first functional layer 3001, the reflected light will come back to the package cavity 101 and be reflected by the reflective inner wall for several times, after such multiple reflection, the central region and the peripheral region of the quantum dot layer 400 reach a similar light intensity, which helps to improve the aging resistance and bleaching resistance of the quantum dot layer 400. In other embodiments, the package cavity 101 does not have the reflective inner wall, it can also reduce the light intensity of the central region, however, compared with the embodiment that has a reflective inner wall, its energy utilization efficiency is lower.

In other words, the light emitted from the LED chip 200 first passes through the first functional layer 3001, reflectivity of the first functional layer 3001 to the smaller angle of incidence of the first light coming from the central region is big, reflectivity of the first functional layer 3001 to the bigger angle of incidence of the first light coming from the peripheral region is small, after the first light passing through the first functional layer 3001, the central region and the peripheral region of the quantum dot layer 400 reach a similar light intensity.

In the present disclosure, the light reflected by the functional layer 300 is further reflected by the reflective inner wall of the concave frame 100, after multiple reflections, it can enter into the quantum dot layer 400 relatively uniformly from various directions, as shown in FIG. 2B.

In the present disclosure, when the second functional layer 3002 is disposed between the LED chip 200 and the quantum dot layer 400 as shown in FIG. 2C, the second functional layer 3002 can let the light having a second polarization state (dotted line shown in FIG. 2C) pass through, and let light having a first polarization state (dashed line shown in FIG. 2C) be reflected, thereby the light intensity in the central region of the quantum dot layer 400 can be relatively weakened. Meanwhile, the reflection of light having the first polarization state by the second functional layer makes the light having the first polarization state lose characteristic of single polarization, i.e. the light becomes circularly polarized light, light having the second polarization state in the reflected light can pass through the second functional layer 3002, light having the first polarization state in the reflected light will be further reflected by the second functional layer 3002, after multiple reflection, light intensity of the central region and the peripheral region of the quantum dot layer 400 can converge.

Further, the functional layer 300 may also function as insulation to prevent heat radiation generated by the LED chip 200 to the quantum dot layer 400, to improve the stability of the quantum dot layer 400.

In some embodiments, the first functional layer has an absorption rate less than 10% with respect to visible light, preferably less than 1%. Throughout the process of the optical reflection and transmission, the first functional layer 3001 absorbs very little visible light, thus the addition of the first functional layer 3001 will not substantially reduce the overall luminescence efficiency of the light-emitting device.

In some embodiments, R≥30%. Preferably, R≥60%. In some embodiments, R=40% or 50% or 60% or 70% or 80% or 90%.

In some embodiments, 0°i≤45°, preferably, 15°<i≤30°. In some embodiments, i≤60° or i≤50°.

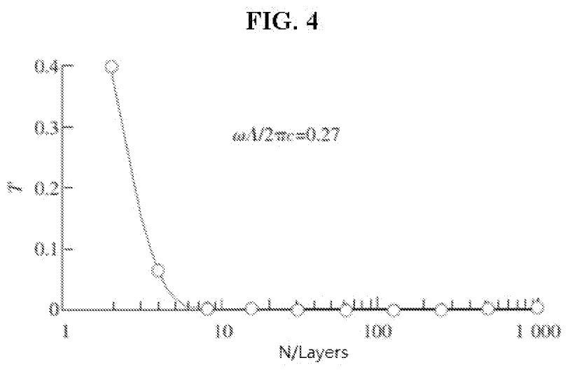

In some embodiments, the material of the first functional layer 3001 is photonic crystal, the photonic crystal material is a kind of periodic ordered structure consisting of two or more materials with different refractive indexes (dielectric constants), also called photonic bandgap material. Visible light with frequency in the photonic band gap cannot propagate in the photonic crystal, Visible light with specific wavelength will be reflected, i.e., so as to produce a photonic crystal structural color. When the number of cycle layer is fewer, the reflectivity of the photonic crystal to light of different incident angles appears different (incident angle of increases, the reflection wavelength red-shifts) and the light is partially reflective and partially transmissive, as shown in FIG. 4. FIG. 4 depicts a relation between the transmittance T of light with frequency in the band gap center of the photonic crystal and the cycle layer N of the photonic crystal in the literature (Yungao Cai et al., “Effects of the cycle layer number and incident angle on the band gap of one-dimensional photonic crystal”, Materials and Structures).

The first functional layer 3001 includes at least one photonic crystal layer. According to the Bragg' law of reflection, 2 dcosθ=nλ, when the wavelength of the first light is specific, the incident angle with which the enhanced light reflection occurs is related to the thickness of the photonic crystal layer

Photonic crystal layer includes one or more of one-dimensional photonic crystal, two-dimensional photonic crystal and three-dimensional photonic crystal. Photonic crystal may be formed by alternative deposition or spin coating of nanomaterials of different refractive indexes such as silicon dioxide, titanium dioxide, polymethyl methacrylate. Two-dimensional photonic crystal may be self-assembled stack of zinc oxide nanowires, titanic nanowires. Three-dimensional photonic crystal may be self-assembled stack of polymethylmethacrylate nanospheres, silica nanoparticles, hollow silica nanospheres and the like. Of course, the one-dimensional photonic crystal, the two-dimensional photonic crystal, or the three-dimensional photonic crystal is not limited to those enumerated above. The average diameter of the nanomaterial of the photonic crystal layer is preferably 200-350 nm.

The thickness of each of the photonic crystal layer may be the same or different. By providing multiple photonic crystal layers with the same thickness, the reflectivity of the first functional layer 3001 to the first light having particular incident angle can be increased. By providing multiple photonic crystal layers of different thickness, the first functional layer 3001 may have a strong reflection to the light having certain range of incident angle.

In some preferred embodiments, the material of the photonic crystal layer has an absorption rate less than 10% with respect to visible light.

In some embodiments, the wavelength of the first light is 400 nm-480 nm. Preferably, the first wavelength of light is 430 nm-470 nm.

In some embodiments, the first functional layer 3001 includes 1 to 6 layers of photonic crystal layer, thickness of each of the photonic crystal layer in the first functional layer 3001 is independently selected from 200 nm-340 nm. Preferably, the first functional layer 3001 includes 1 to 4 layers of photonic crystal layer. The number of layers of the photonic crystal layer shall not be too big to avoid luminance decrease of the quantum dot light-emitting device.

In one particular embodiment, each photonic crystal layer in the first functional layer 3001 includes one-dimensional photonic crystal, the wavelength of the first light is 450 nm, in order to make the reflectivity of the first functional layer 3001 to the first light having incident angle of 0°-30° relatively bigger, the first functional layer 300 may have a photonic crystal layer with thickness of 225 nm, a photonic crystal layer with thickness of 233 nm, and a photonic crystal layer with thickness of 260 nm. The photonic crystal layer with thickness of 225 nm can realize Bragg reflection to the first light having, incident angle of 0°, the photonic crystal layer with thickness of 233 nm can realize Bragg reflection to the first light having incident angle of 15°, the photonic crystal layer with thickness of 260 nm can realize Bragg reflection to the first light having incident angle of 30°. In some embodiments, in order to make the reflectivity of the first functional layer 3001 to the first light having incident angle of 0°-30° reach 60% or more, the first functional layer 3001 includes two layers of photonic crystal layer having a thickness of 225 nm, two layers of photonic crystal layer having a thickness of 233 nm, and two layers of photonic crystal layer having a thickness of 260 nm, i.e. the first functional layer 3001 includes a total of 6 layers of photonic crystal layer.

As shown in FIG. 2A, the concave frame 100 has a package cavity 101, the chip mounting region is located at the bottom of the package cavity 101. LED chip 200 is disposed in the chip mounting, region. In some embodiments, encapsulating material or structure (not shown in figure) is disposed on the LED chip 200 to block external moisture and oxygen.

Part of the first light emitted from the LED chip 200 may emit toward the inner wall of the package cavity 101, since the package cavity 101 is capable of reflecting the first light, after the first light is reflected for multiple times, it finally can reach to the quantum dot layer 400, thereby reducing the loss of light energy.

Functional layer 300 is disposed on the LED chip 200, it shall be understood that the functional layer 300 may be disposed directly on the LED chip 200, or other intermediate layer may be provided between the functional layer 300 and the LED chip 200, such as a barrier layer.

Quantum dot layer 400 is disposed on the functional layer 300, it shall be understood that the quantum dot layer 400 may be disposed directly on the functional layer 300, or the other intermediate layer may be provided between the functional layer 300 and the quantum dot layer 400, for example, water-oxygen barrier layer and the like.

In some embodiments, a first surface (i.e., upper surface) of the quantum dot layer 400 is provided with a first barrier layer (not shown in figure), a second surface (i.e., lower surface) of the quantum dot layer 400 is provided with a second barrier layer (not shown in figure), the first barrier layer and the second barrier layer are transparent layers, the effect of them is water-oxygen barrier to improve the stability of the quantum dot layer 400. In some embodiments, the quantum dot layer 400 is in the shape of thin film, or plate. Quantum dot layer 400 may have a curved or uneven portion, its inner layer may have a non-uniform thickness, its thickness may be as thin as nanometer-scale thickness, may also be as thick as centimeter-scale thickness, to conform to a specific quantum dot photoluminescence product.

In some embodiments, the quantum dot layer 400 includes a resin matrix and a quantum dot light emitting material dispersed in the resin matrix, the quantum dot light emitting material is adapted to emit a second light after excited by the first light.

The area of the functional layer 300 may be greater than, less than or equal to the area of the quantum dot layer 400. In some embodiments, the functional layer 300 is disposed opposite to the central region of the LED chip 200. i.e., the functional layer 300 faces the region with the maximum light intensity of the LED chip 200.

In some embodiments, the area of the functional layer 300 may be greater than or equal to the area of the LED chip 200.

In some embodiments, the number of the LED chip 200 may be plural, so the quantum dot layer and the functional layer correspond to the plurality of LED chips 200. By disposing a plurality of LED chips, it has certain degree of uniform distribution effect on the light intensity of the quantum dot layer received. The area of a functional layer 300 can sufficiently cover the plurality of LED chips 200.

In some embodiments, the reflectivity of the second functional layer 3002 to the light having first polarization state is greater than or equal to 80%, the transmissivity of the second functional layer 3002 to the light having second polarization state is greater than or equal to 80%.

In some embodiments, the reflectivity of the second functional layer 3002 to the light having first polarization state is greater than or equal to 70%, the transmissivity of the second functional layer 3002 to the light having second polarization state is greater than or equal to 70%.

In some embodiments, the thickness of the second functional layer 3002 may be 5 μm-500 μm. In some embodiments, the thickness of the second functional layer 3002 may be 5-200 μm. In some embodiments, the thickness of the second functional layer 3002 may be 25 μm-100 μm.

In some embodiments, the number of the chip mounting region is multiple, a reflective film is disposed between the multiple chip mounting regions, to improve the light output efficiency. Electrical connection between the LED chips can refer to the prior art.

In some embodiments, the quantum dot light-emitting device 100 does not include a concave frame. Other features are as described above.

The present disclosure further provides a display apparatus including the quantum dot light-emitting device according to the present disclosure. Since the quantum dot light-emitting device has good luminescence stability, so that the display device has a long lifetime.

### Example 1

(1) Preparation of quantum dot composite layer: a PVA (having degree of polymerization of 17,000, molecular weight of about 75,000, degree of hydrolysis greater than 98%) aqueous polymer solution, and a CdSe/CdS quantum dot solution were prepared separately, the quantum dot solution was added to the PVA aqueous polymer solution, and the mixture was stirred at a speed of 3000 rpm for 3 min, so a dispersion was prepared. The dispersion was coated on a PET substrate to form, a wet film with thickness of 100 microns, then solvent was evaporated to obtain the quantum dot composite layer with 10 microns thickness. Details of the preparation method of the quantum dot composite layer may refer to the published patent CN108865112A.

(2) Preparation of functional layer: toluene solution containing hollow SiO₂ microspheres (mass concentration of 1%, average particle diameter of 225 nm) and an acrylate adhesive (mass concentration of 0.3%) was provided, the solution was spin-coated on the quantum dot composite layer, firstly it was spin-coated at a speed of 300 rpm for 30 s, and then spin-coated at a speed of 2000 rpm for 1 min, then baked at 80° C. for 5 min; after the solvent was evaporated, cured with 500 mj/cm² high pressure mercury lamp; after curing, one layer of photonic crystal layer was prepared on the quantum dot composite layer, the thickness of the photonic crystal layer was one layer of the hollow SiO₂ microspheres which approximately equaled to the particle diameter of 225 nm, i.e., thickness of the functional layer was about 225 nm. The surface structure of the functional layer by theoretical simulation satisfied that the reflectivity towards blue light having angle of incidence equal to 0° and wavelength of 450 nm is 30% or more, the reflectivity towards blue light having angle of incidence greater than 0° and wavelength of 450 nm is less than 30%.

(3) Preparation of a light-emitting device: a LED chip was mounted on a concave reflection-type circuitry substrate with a precision dispenser, the emitting light of LED chip is blue light having a wavelength of 450 nm. Silicone adhesive was disposed on the exposed surface of the LED chip, the quantum dot composite layer and functional layer were disposed on the surface of the silicone adhesive away from the LED chip, and the functional layer was in contact with the silicone adhesive, silicone adhesive layer and the functional layer were bonded after curing the silicone adhesive. A transparent adhesive layer was disposed on the quantum dot composite layer away from the surface of the functional layer, the transparent adhesive layer had a thickness of 50 microns, the material of the transparent adhesive layer was modified silicone. Details of the preparation method of the light-emitting device can be referred to the published patent CN109545943A.

### Example 2

The difference between Example 2 and Example 1 was: in step (2), toluene solution containing hollow SiO₂ microspheres (mass concentration of 3%, average particle diameter of 225 nm) and an acrylate adhesive (mass concentration of 0.8%) was provided, the solution was spin-coated on the quantum dot composite layer, firstly it was spin-coated at a speed of 300 rpm for 30 s, and then spin-coated at a speed of 2000 rpm for 1 min, then baked at 80° C. for 5 min; after the solvent was evaporated, cured with 500 mj/cm² high pressure mercury lamp; after curing, two layers of photonic crystal layer were prepared on the quantum dot composite layer, the thickness of each photonic crystal layer was one layer of the hollow SiO₂ microspheres which approximately equaled to particle diameter of 225 nm, i.e., thickness of the functional layer was about 450 nm. The surface structure of the functional layer by theoretical simulation satisfied that the reflectivity towards blue light having angle of incidence equal to 0° and wavelength of 450 nm is 60% or more, the reflectivity towards blue light having angle of incidence greater than 0 and wavelength of 450 nm is less than 60%.

### Example 3

The difference between Example 3 and Example 1 was: in step (2), toluene solution containing hollow SiO₂ microspheres (mass concentration of 3%, average particle diameter of 225 nm) and an acrylate adhesive (mass concentration of 0.8%) was provided, the solution was spin-coated on the quantum dot composite layer, firstly it was spin-coated at a speed of 300 rpm for 30 s, and then spin-coated at a speed of 2000 rpm for 1 min, then baked at 80° C. for 5 min; after the solvent was evaporated, cured with 500 mj/cm² high pressure mercury lamp; after curing, two layers of photonic crystal layer A were prepared on the quantum dot composite layer, the thickness of each photonic crystal layer A was about a layer of hollow SiO₂ microspheres which approximately equaled to particle diameter of 225 urn, then using the same process to form two layers of photonic crystal layer B on the photonic crystal layer A, the thickness of each photonic crystal layer B was about a layer of hollow microspheres which approximately equaled to particle diameter of 233 nm, then again using the same process to form two layers of photonic crystal layer C on the photonic crystal layer B, the thickness of each photonic crystal, layer C was about a layer of hollow SiO₂ microspheres which approximately equaled to particle diameter of 260 nm. The surface structure of the functional layer by theoretical simulation satisfied that the reflectivity towards blue light having angle of incidence equal to 30 and wavelength of 450 nm is 60% or more, the reflectivity towards blue light having angle of incidence greater than 30 and wavelength of 450 nm is less than 60%.

### Example 4

The difference between Example 4 and Example 3 was: in step (2), using the same process to form two layers of photonic crystal layer D on the photonic crystal layer C, the thickness of each photonic crystal layer D was about a layer of hollow SiO₂ microspheres which approximately equaled to particle diameter of 318 nm. The surface structure of the functional layer by theoretical simulation satisfied that the reflectivity towards blue light having angle of incidence equal to 45° and wavelength of 450 nm is 60% or more, the reflectivity towards blue light having angle of incidence greater than 45° and wavelength of 450 mu is less than 60%.

### Example 5

The difference between Example 5 and Example 1 was: in step (2), n-octane solution containing the zinc oxide nanorods (mass concentration of 1%, diameter of 225 nm, length of about 1 μm), and silicone adhesive (mass concentration of 0.3%) was scrape-coated over the quantum dot composite layer, and then baked at 60° C. for 5 min, the ZnO nanorods self-assembled and formed two-dimensionally oriented structure in the solvent evaporation process; after curing 1 h at 130° C., a functional layer made of the photonic crystal layer was formed on the quantum dot composite layer, the thickness of the photonic crystal layer was about 1 layer of ZnO nanorods which approximately equaled to the diameter of 225 nm, i.e., the thickness of the functional layer was about 225 nm.

### Example 6

The difference between Example 6 and Example 1 was: in step (2), one surface of the quantum dot composite layer was covered by a protective film, and the opposite surface of it was exposed, ZnO layer having a thickness of 225 nm was deposited on the exposed surface of the quantum dot composite layer by atomic layer deposition (ALD) deposition furnace, and then acrylate adhesive layer was formed by spin-coating and had a thickness of 225 nm, after curing, the above process was repeated once, then four layers of one-dimensional photonic crystal layer containing ZnO/acrylate/ZnO/acrylate were formed on the quantum dot composite layer.

### Example 7

The difference between Example 7 and Example 1 was: in step (2), toluene solution containing hollow SiO₂ microspheres (mass concentration of 1%, average particle diameter of 200 nm) and an acrylate adhesive (mass concentration of 0.3%) was provided, the solution was spin-coated on the quantum dot composite layer, firstly spin-coated at a speed of 300 rpm for 30 s, and then spin-coated at a speed of 2000 rpm for 1 min, then baked at 80° C. for 5 min; after the solvent was evaporated, cured with 500 mj/cm² high pressure mercury lamp; after curing, one layer of photonic crystal layer was prepared on the quantum dot composite layer, the thickness of the photonic crystal layer was one layer of the hollow SiO₂ microspheres which approximately equaled to particle diameter of 200 nm, i.e., thickness of the functional layer was about 200 nm. The surface structure of the functional layer by theoretical simulation satisfied that reflectivity towards blue light having angle of incidence equal to 0° and wavelength of 400 nm is 30% or more, reflectivity towards blue light having angle of incidence greater than 0° and wavelength of 400 nm is less than 30%.

In step (3), LED chip emitted blue light of a wavelength of 400 nm.

### Example 8

The difference between Example 8 and Example 1 was: in step (2), toluene solution containing hollow SiO₂ microspheres (mass concentration of 1%, average particle diameter of 240 nm) and an acrylate adhesive (mass concentration of 0.3%) was provided, the solution was spin-coated on the quantum dot composite layer, firstly spin-coated at a speed of 300 rpm for 30 s, and then spin-coated at a speed of 2000 rpm for 1 min, then baked at 80° C. for 5 min; after the solvent was evaporated, cured with 500 mj/cm² high pressure mercury lamp; after curing, one layer of photonic crystal layer was prepared on the quantum dot composite layer, the thickness of the photonic crystal layer was one layer of the hollow SiO₂ microspheres which approximately equaled to particle diameter of 240 nm, i.e., thickness of the functional layer was about 240 nm. The surface structure of the functional layer by theoretical simulation satisfied that the reflectivity towards blue light having angle of incidence equal to 0 and wavelength of 480 nm is 30% or more, the reflectivity towards blue light having angle of incidence greater than 0° and wavelength of 480 not is less than 30%.

In step (3), LED chip emitted blue light of a wavelength of 480 nm.

### Example 9

The difference between Example 9 and Example 1 was: in step (2), toluene solution containing hollow SiO₂ microspheres (mass concentration of 3%, average particle diameter of 240 nm) and an acrylate adhesive (mass concentration of 0.8%) was provided, the solution was spin-coated on the quantum dot composite layer, firstly spin-coated at a speed of 300 rpm for 30 s, and then spin-coated at a speed of 2000 rpm for 1 min, then baked at 80° C. for 5 min; after the solvent was evaporated, cured with 500 mj/cm² high pressure mercury lamp; after curing, two layers of photonic crystal layer E were prepared on the quantum dot composite layer, the thickness of each photonic crystal layer E was about a layer of hollow SiO₂ microspheres, i.e., particle diameter of 240 nm, then using the same process to form two layers of photonic crystal layer F on photonic crystal layer E, the thickness of each photonic crystal layer F was about a layer of hollow SiO₂ microspheres, i.e., particle diameter of 248 nm, then again using the same process to form two layers of photonic crystal layer U on the photonic crystal layer F, the thickness of each photonic crystal layer G was about 1 layer of hollow SiO₂ microspheres which approximately equaled to particle diameter of 277 nm, then again using the same process to form two layers of photonic crystal layer G on the photonic crystal layer H, the thickness of each photonic crystal layer H was about a layer of hollow SiO₂ microspheres which approximately equaled to particle diameter of 340 nm. The surface structure of the functional layer by theoretical simulation satisfied that reflectivity towards blue light having angle of incidence equal to 45 and wavelength of 480 nm is 60% or more, reflectivity towards blue light having angle of incidence greater than 45 and wavelength of 480 mu is less than 60%.

In step (3), LED chip emitted blue light of a wavelength of 480 nm.

### Example 10

The difference between Example 10 and Example 1 was the preparation of the functional layer, inventor directly purchased 3M brand VIKUITI™ DBEF D200 type reflective polarizing film (corresponding to the second functional layer) having a thickness of 200 μm from the market, and cut it with appropriate size.

### Comparative Example 1

The difference between Comparative Example 1 and Example 1 was that it did not include the step (2), and in step (3), the quantum composite layer was disposed on the surface of silicone away from the LED chip.

Photoluminescence lifetime of the light-emitting devices of the above respective examples were tested. Photoluminescence lifetime was calculated as follows:

(1) Acceleration factor (AF) was calculated by the Arrhenius model:

$$AF = exp [ \frac{{E}_{a}}{K} \times ( \frac{1}{{T}_{u}} - \frac{1}{{T}_{s}} ) ] ;$$

activation energy Eₐ is between 0.46 to 0.5, 0.48 was adopted, under normal use at room temperature (under non-aging conditions), when the lighting current was 20 mA, the center temperature Tᵤ of the quantum dot layer was 55° C., when the lighting current was 60 mA, the center temperature Tᵤ of quantum dot layer was 75° C., K is Boltzmann constant.

(2) Aging, condition 1: aging under 60 lighting current of 20 mA, the measured center temperature Tₛ of the quantum dot layer of the light-emitting device was 75° C., the calculated AF1 was 2.65.

(3) Aging condition 2: aging under 60 lighting current of 60 mA, the measured center temperature Tₛ of the quantum dot layer of the light-emitting device was 95° C., the calculated AF2 was 2.39.

(4) Predicted lifetime L70:

$$L 70 = \frac{ln 0.7}{ln Δ K} * Δ T * AF ;$$

wherein ΔK is the decay ratio of luminance after aging, ΔT=time interval between the end time of aging and the time reaching the highest luminance value.

Maintaining ΔT=1000 h, ΔK₁ and ΔK₂ of the quantum dot light-emitting devices of examples and comparative example subjected to the aging condition 1 and 2 were measured. ΔK₁ and ΔK₂ were obtained by measuring the luminance decay curve of light-emitting device under a preset condition, AF value at aging condition 1 and 2 were named AF1 and AF2 respectively, lifetime of each quantum dot light-emitting device was calculated.

In Table 1, ΔK₁ of quantum dot light-emitting devices of examples and comparative example under the conditions of 60° C. and 20 mA was reported, ΔK₂ of quantum dot light-emitting devices of examples and comparative example under the conditions of 60° C. and 60 mA was also reported.

In Table 1, lifetime I was the calculated predicted lifetime under aging condition 1, lifetime 2 was the calculated predicted lifetime under aging condition 2.

TABLE 1

| | ΔK₁(60° | ΔK₂(60° | Lifetime 1(60° | Lifetime 2(60° |
|---|---|---|---|---|
| | C./20 mA) | C./60 mA) | C./20 mA) | C./60 mA) |
| Example 1 | 97.0% | 95.1% | 31077 h | 16944 h |
| Example 2 | 97.5% | 96.3% | 37388 h | 22580 h |
| Example 3 | 98.5% | 97.5% | 62631 h | 33624 h |
| Example 4 | 98.6% | 97.6% | 67138 h | 35043 h |
| Example 5 | 96.0% | 94.3% | 23188 h | 14505 h |
| Example 6 | 97.1% | 94.9% | 32165 h | 16263 h |
| Example 7 | 96.2% | 95.2% | 24434 h | 17306 h |
| Example 8 | 97.5% | 96.2% | 37388 h | 21974 h |
| Example 9 | 98.8% | 97.9% | 78407 h | 40111 h |
| Example 10 | 97.2% | 94.7% | 33331 h | 15633 h |
| Comparative | 95.8% | 85.4% | 22061 h | 5394 h |
| Example 1 | | | | |

From the results of the lifetime performance after aging in the examples and comparative example, the present disclosure can effectively improve the lifetime of the quantum dot light-emitting device under working condition of high current and high light intensity, and under the aging conditions, the luminance decay ratio is relatively low, the luminescence stability is good.

The above described the basic principles, main features, and the advantages of the present disclosure. Those skilled in the industry will understand that the present disclosure is not limited by the above embodiments, the embodiments and the specification described above only described the principles of the present disclosure, and there will be a variety modification and improvements without departing from the spirit and scope of the present disclosure. These modifications and improvements also, fall within the scope of the claims. The protection scope is defined by the appended claims and their equivalents.

What is claimed is:

1. A quantum dot light-emitting device, comprising a concave frame having a chip mounting region, wherein, further comprising:
a light-emitting diode chip disposed in the chip mounting region, the light-emitting diode chip adapted to emit a first light;
a quantum dot layer disposed on the light exit direction of the light-emitting diode chip;
a functional layer disposed between the light-emitting diode chip and the quantum dot layer, the functional layer is a first functional layer or a second functional layer; the first functional layer has a reflectivity greater than or equal to R with respect to the first light having angle of incidence less than or equal to i, and the first functional layer has a reflectivity less than R with respect to the first light having angle of incidence greater than i, wherein R≤90%, i>0; the second functional layer is a reflective polarizing film layer, the second functional layer reflects light having a first polarized state in the first light and transmits light having a second polarized state in the first light, the light having the first polarized state is orthogonal to the light having the second polarized state.

2. The quantum dot light-emitting device according to claim 1, wherein, the first functional layer has an absorption rate less than 10% with respect to visible light.

3. The quantum dot light-emitting device according to claim 1, wherein, R≥30%.

4. The quantum dot light-emitting device according to claim 1, wherein, 0°<i≤45°.

5. The quantum dot light-emitting device according to claim 1, wherein, the quantum dot light-emitting device further comprising a first barrier layer and a second barrier layer disposed on a first surface and a second surface of the quantum dot layer respectively.

6. The quantum dot light-emitting device according to claim 1, wherein, the functional layer is disposed opposite to the region having the maximum light intensity of the light-emitting diode chip.

7. The quantum dot light-emitting device according to claim 1, wherein, the second functional layer has a reflectivity greater than or equal to 80% with respect to the light having the first polarized state, the second functional layer has a transmissivity greater than or equal to 80% with respect to the light having the second polarized state.

8. The quantum dot light-emitting device according to claim 1, wherein, the wavelength of the first light is 400 nm-480 nm.

9. The quantum dot light-emitting device according to claim 1, wherein, the first functional layer comprises at least one photonic crystal layer, the photonic crystal layer comprises one or more of one-dimensional photonic crystal, two-dimensional photonic crystal and three-dimensional photonic crystal.

10. The quantum dot light-emitting device according to claim 9, wherein, the first functional layer comprises 1 to 6 layers of the photonic crystal layer, a thickness of each of the photonic crystal layer is the same or different, the thickness of each photonic crystal layer is 200 nm-340 nm.

11. The quantum dot light-emitting device according to claim 1, wherein, the quantum dot light-emitting device does, not comprise the concave frame.

12. A display device, wherein, the display device comprises the quantum dot light-emitting device according to claim 1.

13. (canceled)

14. The quantum dot light-emitting device according to claim 2, wherein, the first functional layer comprises at least one photonic crystal layer, the photonic crystal layer comprises one or more of one-dimensional photonic crystal, two-dimensional photonic crystal and three-dimensional photonic crystal.

15. The quantum dot light-emitting device according to claim 3, wherein, the first functional layer comprises at least one photonic crystal layer, the photonic crystal layer comprises one or more of one-dimensional photonic crystal, two-dimensional photonic crystal and three-dimensional photonic crystal.

16. The quantum dot light-emitting device according to claim 4, wherein, the first functional layer comprises at least one photonic crystal layer, the photonic crystal layer comprises one or more of one-dimensional photonic crystal, two-dimensional photonic crystal and three-dimensional photonic crystal.

17. The quantum dot light-emitting device according to claim 5, wherein, the first functional layer comprises at least one photonic crystal layer, the photonic crystal layer comprises one or more of one-dimensional photonic crystal, two-dimensional photonic crystal and three-dimensional photonic crystal.

18. The quantum dot light-emitting device according to claim 6, wherein, the first functional layer comprises at least one photonic crystal layer, the photonic crystal layer comprises one or more of one-dimensional photonic crystal, two-dimensional photonic crystal and three-dimensional photonic crystal.
